(19) United States
(12) Patent Application Publication
(10) Pub. No.: US 2015/0179508 A1
(43) Pub. Date: Jun. 25, 2015

(54) Tantalum-Based Copper Barriers and Methods for Forming the Same

(71) Applicant: INTERMOLECULAR INC., San Jose, CA (US)

(72) Inventors: Edwin Adhiprakasha, Mountain View, CA (US); Sean Barstow, San Jose, CA (US); Frank Greer, Pasadena, CA (US); Wenxian Zhu, E. Palo Alto, CA (US)

(73) Assignee: INTERMOLECULAR INC., San Jose, CA (US)

(21) Appl. No.: 14/138,628

(22) Filed: Dec. 23, 2013

(51) Int. Cl. H01L 21/768; H01L 23/532

(52) U.S. Cl. CPC H01L 21/76832; H01L 23/53238; H01L 21/76805; H01L 21/76843

(57) ABSTRACT

Embodiments described herein provide tantalum-based copper barriers and methods for forming such barriers. A dielectric body is provided. A first layer is formed above the dielectric body. The first layer includes tantalum. A second layer is formed above the first layer. The second layer includes manganese. A third layer is formed above the second layer. The third layer includes copper.

### TECHNICAL FIELD

The present invention relates to copper barriers, such as those used in via trenches formed in interlayer dielectrics (ILDs). More particularly, this invention relates to improved tantalum-based copper barriers and methods for forming such copper barriers.

### BACKGROUND OF THE INVENTION

As the feature sizes of microelectronic assemblies (e.g., integrated circuits) continue to get smaller, manufacturing challenges become more apparent. For example, as the vias or interconnects, often made of copper, formed through interlayer dielectrics (ILDs) shrink in size with less distance separating adjacent vias, it becomes more difficult to form barrier layers within the via trenches which adequately prevent the copper from diffusing into the dielectric material, and possibly causing a short.

In recent years, tantalum nitride has been used with some success. However, as the thickness of the tantalum nitride is reduced to levels suitable for next generation devices (e.g., less than 0.1 nm), it often allows for an undesirable amount of copper diffusion, particularly under relatively high temperatures (e.g., 350° C. and higher).

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a dielectric body according to some embodiments.

FIG. 2 is a cross-sectional view of the dielectric body of FIG. 1 with a first layer formed above.

FIG. 3 is a cross-sectional view of the dielectric body of FIG. 2 with a second layer formed above the first layer.

FIG. 4 is a cross-sectional view of the dielectric body of FIG. 3 with a third layer formed above the second layer.

FIG. 5 is a cross-sectional view of the dielectric body of FIG. 4 with a copper body formed above the third layer.

FIGS. 6-11 are tables of data related to samples of various barrier layer stacks.

FIG. 12 is a cross-sectional view of a microelectronic assembly according to some embodiments.

FIG. 13 is a simplified cross-sectional diagram illustrating a physical vapor deposition (PVD) tool according to some embodiments.

FIG. 14 is a simplified cross-sectional diagram illustrating an atomic layer deposition (ALD) tool according to some embodiments.

FIG. 15 is a flow chart illustrating a method for forming a copper barrier according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide methods for forming copper barriers (or barrier layer stacks) on, for example, dielectrics, such as interlayer dielectrics (ILDs). More particularly, methods are provided for improving the copper-barrier properties of tantalum-based layers, such as those formed in via (or interconnect) trenches. The methods described herein are particularly useful for future generation devices in which the feature sizes will continue to shrink (e.g., smaller/narrower trenches).

In some embodiments, the copper-barrier properties of tantalum-based layers are improved by forming a manganese-containing layer between the tantalum-based layer and the copper seed layer which is typically deposited before the via or interconnect (e.g., copper) is formed. In some embodiments, the manganese-containing layer has a thickness of between about 0.5 nanometers (nm) and about 2.5 nm and is formed using physical vapor deposition (PVD). In some embodiments, the manganese-containing layer is made of manganese nitride, has a thickness of between about 0.1 nm and about 0.5 nm, and is formed using PVD or atomic layer deposition (ALD).

The tantalum-based layer may be made of tantalum nitride (e.g., 0.3-5 nm) and formed using ALD or PVD. The copper seed layer may have a thickness of between about 5 nm and about 100 nm and formed using various methods (e.g., PVD, CVD, etc.).

The various layers may be formed in a trench formed in/on an upper surface of a dielectric material (i.e., an ILD, such as silicon oxide). A copper via may also be formed in the trench and be electrically connected to a device (e.g., a transistor) formed on the underlying substrate.

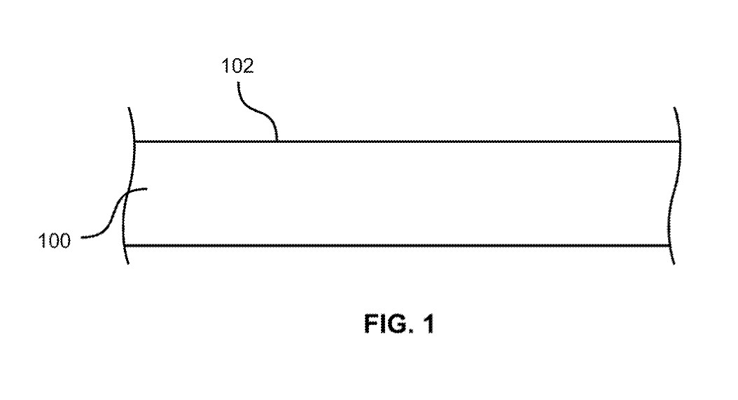

FIGS. 1-5 illustrate a method for forming a copper barrier according to some embodiments. Referring now to FIG. 1, a dielectric body 100 is provided. In some embodiments, the dielectric body is made of a dielectric material, such as silicon oxide, silicon nitride, a high-k dielectric (e.g., having a dielectric constant greater than 3.9), such as zirconium oxide, hafnium oxide, or aluminum oxide, or a combination thereof. Although the dielectric body 100 is shown as a substrate, it should be understood that in some embodiments the dielectric body 100 is a dielectric layer formed above a substrate (e.g., semiconductor), such an interlayer dielectric (ILD).

Further, although the dielectric body 100 is shown as being arranged such that a surface 102 thereof is horizontal, it should be understood that in some embodiments, the surface 102 may form a side wall of a trench formed in a dielectric material (e.g., a trench formed in an ILD, such that the surface is substantially vertical to a surface of a substrate over which the ILD is formed). In such embodiments, the layers described below as being formed above the dielectric body 100 may be formed on the side walls, as well as the bottom, of the trench.

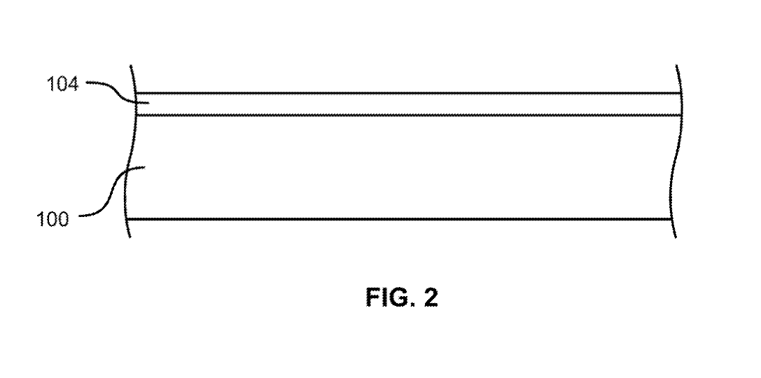

As shown in FIG. 2, a first barrier layer (or simply a first layer) 104 is formed above the dielectric body 100 (e.g., above the surface 102 thereof). In some embodiments, the first barrier layer 104 includes tantalum. The first barrier layer 104 may be made of tantalum nitride. In some embodiments, the first barrier layer is formed using ALD and has a thickness of, for example, between about 0.3 nm and about 5 nm.

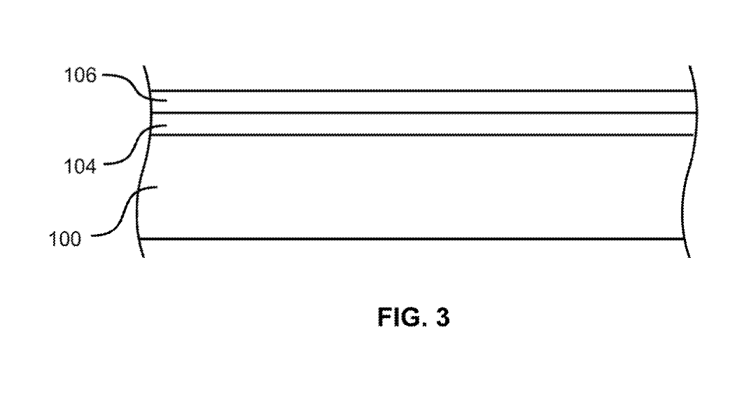

Referring to FIG. 3, a second barrier layer (or simply a second layer) 106 is then formed above the first barrier layer 104. In some embodiments, the second barrier layer 106 includes manganese. The second barrier layer 106 may be made of manganese, manganese nitride, or a combination thereof. The second barrier layer may have a thickness of, for example, between about 0.1 nm and about 5 nm.

In embodiments in which the second barrier layer 106 is made of manganese, the second barrier layer 106 may have a thickness of, for example, between about 0.5 nm and about 2.5 nm. In such embodiments, the second barrier layer 106 may be formed using PVD.

In embodiments in which the second barrier layer 106 is made of manganese nitride, the second barrier layer 106 may have a thickness of, for example, between about 0.1 nm and about 0.5 nm. In such embodiments, the second barrier layer 106 may be formed using PVD or ALD.

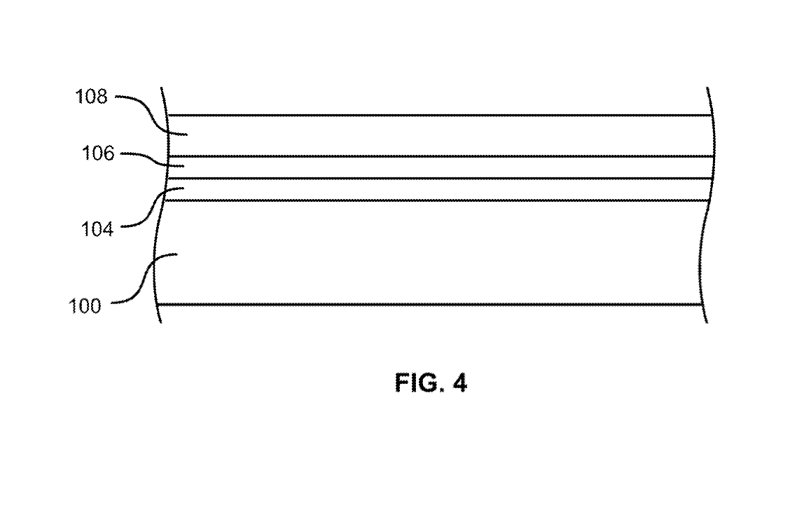

As shown in FIG. 4, a seed layer (or a third layer) 108 is then formed above the second barrier layer 106. In some embodiments, the seed layer 108 is made of copper and has a thickness of, for example, between about 5 nm and about 100 nm. The seed layer 108 may be formed using, for example, PVD.

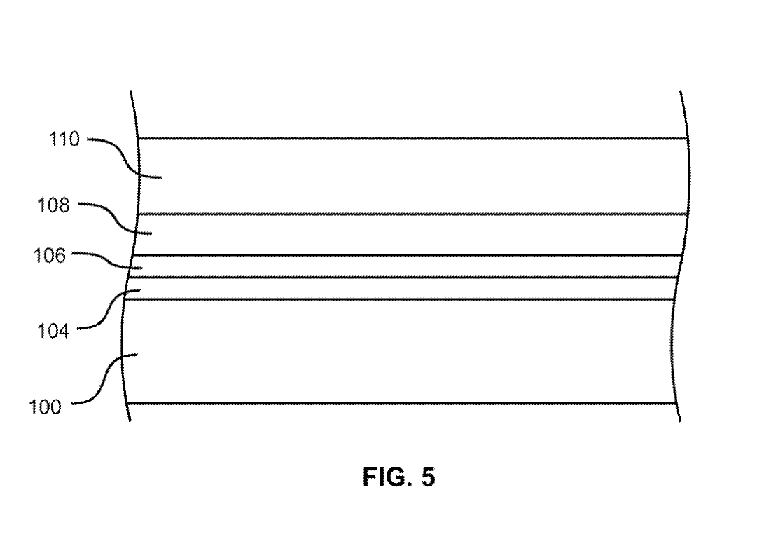

Referring to FIG. 5, a copper body 110 is then formed above the seed layer 108. The copper body 110 may be formed using, for example, PVD or an electroplating process. The first barrier layer 104 and the second barrier layer 106 (perhaps in combination with the seed layer 108) may be considered to form a barrier layer stack which, for example, prevents copper from the copper body 110 (and/or the seed layer 108) from diffusing into the dielectric body 100. The second barrier layer 106 may also improve the adhesion of the seed layer 108 (and/or the copper body 110) on the first barrier layer 104. In some embodiments, the copper body 110 is a conductive via or interconnect formed in a trench in an ILD.

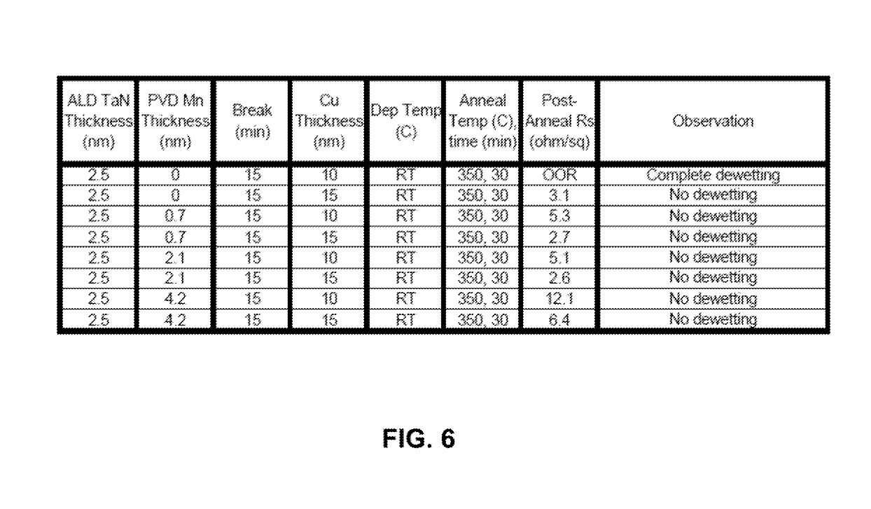

FIGS. 6-11 are tables showing data related to various samples of barrier layer stacks, some of which are formed in accordance with some embodiments described herein (e.g., barrier layer stacks which include the manganese-containing layer described above).

Referring to FIG. 6, each of the barrier layer stack samples was formed above a 300 nm (thick) silicon oxide layer on a silicon substrate. 2.5 nm tantalum nitride layers were first formed above the silicon oxide layers using ALD. Manganese layers of various thicknesses (0.7 nm, 2.1 nm, and 4.2 nm) were then formed above some of the tantalum nitride layers using PVD. After a 15 minute break (e.g., a vacuum break in which the samples are exposed to the atmosphere), copper layers (10 nm and 15 nm) were formed above the samples. The samples were then annealed at 350° C. for 30 minutes.

As shown in FIG. 6, none of the 15 nm copper layers dewetted from the tantalum nitride layers. However, the 10 nm copper layers completely dewetted from the tantalum nitride layers when the manganese layer was not included, but no dewetting occurred when any of the manganese layers (i.e., 0.7 nm, 2.1 nm, or 4.2 nm) were used. Thus, the data in FIG. 6 indicates that the presence of the manganese layer improves the adhesion of copper on the tantalum nitride. It should also be noted that the use of the 0.7 nm and 2.1 nm manganese layers did not significantly affect (post-anneal) sheet resistance.

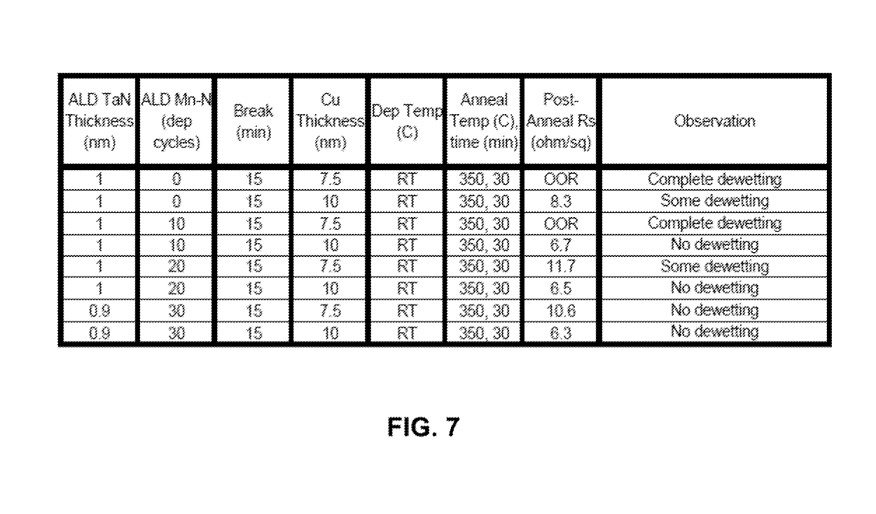

Referring to FIG. 7, each of the samples was formed above a 300 nm silicon oxide layer on a silicon substrate. 0.9 nm and 1 nm tantalum nitride layers were first formed above the silicon oxide layers using ALD. Manganese nitride layers were then formed above some of the tantalum nitride layers using ALD with various deposition cycle durations (e.g., 10 seconds, 20 second, and 30 seconds). Although not shown, the resulting ALD barriers (i.e., the tantalum nitride and the manganese nitride) each had a total thickness of less than 1.2 nm. After a 15 minute break (e.g., vacuum break), copper layers (7.5 nm and 10 nm) were formed above the samples. The samples were then annealed at 350° C. for 30 minutes.

As shown in FIG. 7, none of the 10 nm copper layers exhibited any dewetting from the tantalum nitride layers when the manganese nitride was used in combination with the tantalum nitride. However, at least some dewetting occurred when the manganese nitride was not used and the 7.5 nm copper layer was formed above the manganese nitride from the 20 second ALD cycle. Thus, the data in FIG. 7 indicates that the presence of the manganese nitride layer improves the adhesion of copper on the tantalum nitride, particularly as the duration of the ALD deposition cycle used to deposit the manganese nitride increases. It should also be noted that the use of the manganese nitride layer formed with the 10 second ALD cycle decreased the sheet resistance for the 10 nm copper layer (compared to the sample not having the manganese nitride layer).

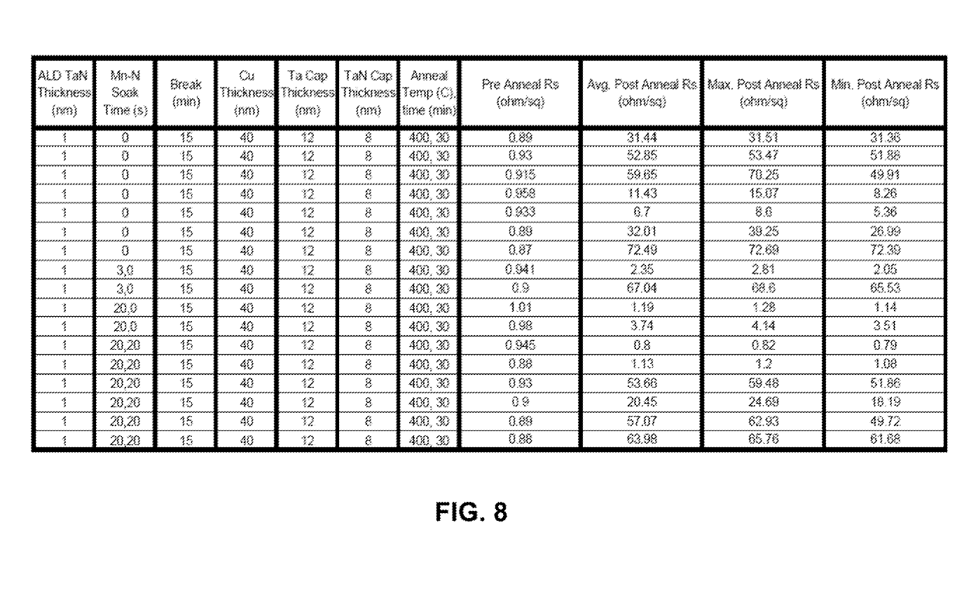

Referring to FIG. 8, each of the samples was formed above a high resistivity silicon substrate. 1 nm tantalum nitride layers were first formed above the substrates using ALD. Manganese nitride layers were then formed above some of the tantalum nitride layers using single ALD “soak” cycles of various durations. In the depicted examples, the soak cycle durations were 3 seconds/0 seconds, 20 seconds/0 seconds, and 20 seconds/20 seconds, where the first time refers to the flow time of the first precursor, and the second time refers to the flow time of the second precursor. After a 15 minute break (e.g., vacuum break), 40 nm copper layers were formed, followed by capping layers of 12 nm of tantalum and 8 nm of tantalum nitride (both formed using PVD). The samples were then annealed at 400° C. for 30 minutes. As can be seen in FIG. 8, regardless of the presence of the manganese nitride layer, the sheet resistance of the barrier layer stacks changed considerably after the annealing process. Thus, the data in FIG. 8 indicates that the barrier layer stacks having the manganese nitride layer, when formed with single ALD soak cycles, are not consistently resistant to copper diffusion at 400° C.

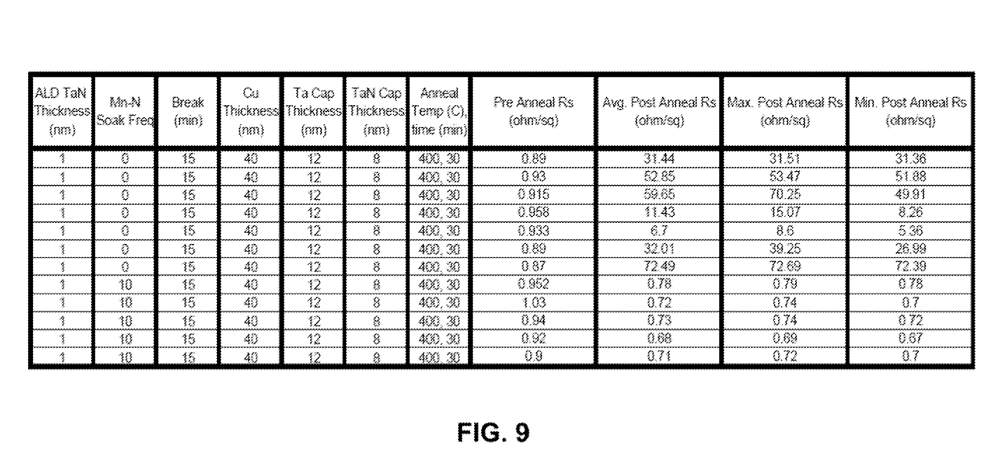

The samples depicted in FIG. 9 were formed in a manner similar to those of FIG. 8. However, in the samples which included the manganese nitride layer, the manganese nitride layer was formed with ten ALD soak cycles. As can be seen in FIG. 9, the resulting barrier stacks with the manganese nitride layer exhibited little change in sheet resistance after the annealing process. In fact, the sheet resistance of the barrier layer stacks with the manganese nitride layer actually decreased after the annealing process. Thus, the data in FIG. 9 indicates that the barrier layer stacks having the manganese nitride layer, when formed with ten ALD soak cycles, are consistently resistant to copper diffusion at 400° C.

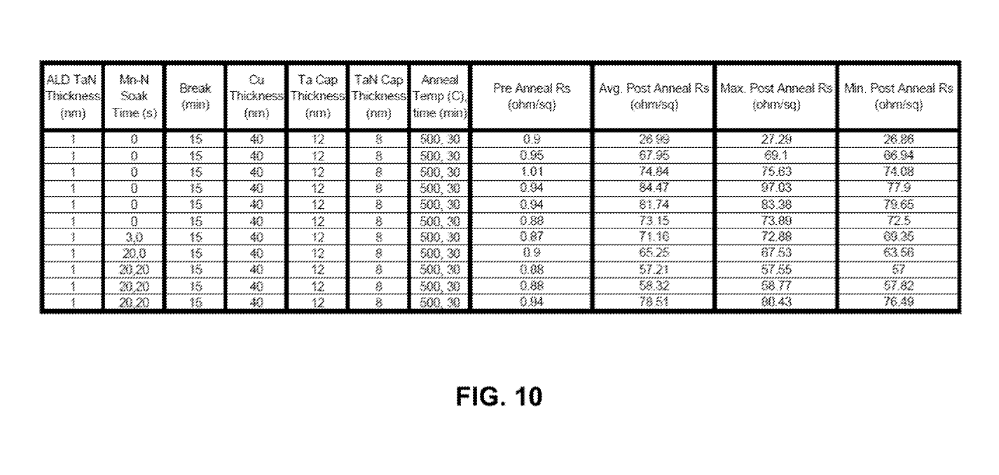

The samples depicted in FIG. 10 were formed in a manner similar to those of FIG. 8. However, the annealing process was performed at 500° C. (rather than 400° C.) for 30 minutes. As can be seen in FIG. 10, regardless of the presence of the manganese nitride layer (i.e., formed with a single ALD soak cycle), the sheet resistance of the barrier layer stacks changed considerably after the annealing process. Thus, the data in FIG. 10 indicates that the barrier layer stacks having the manganese nitride layer, when formed with single ALD soak cycles, are not consistently resistant to copper diffusion at 500° C.

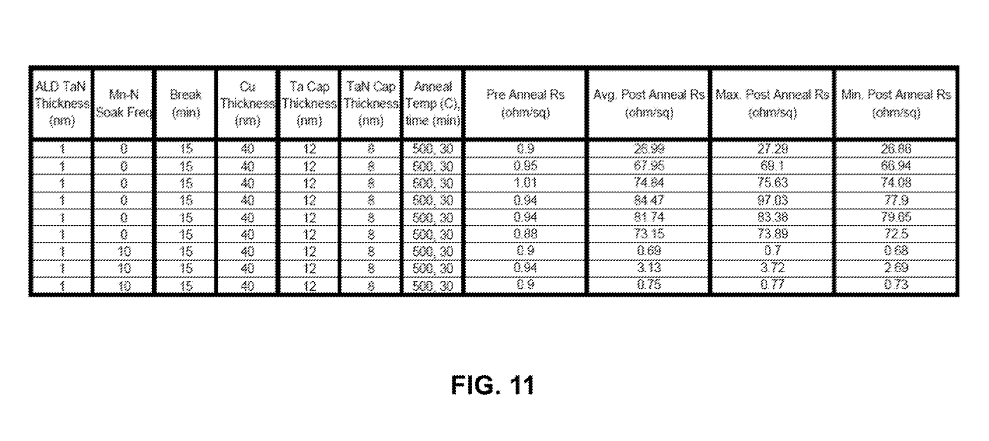

The samples depicted in FIG. 11 were formed in a manner similar to those of FIG. 9 (i.e., the manganese nitride layer was formed with ten ALD soak cycles). However, the annealing process was performed at 500° C. (rather than 400° C.) for 30 minutes. As can be seen in FIG. 9, the resulting barrier layer stacks exhibited little change in sheet resistance after the annealing process. In fact, the sheet resistance of the samples actually decreased after the annealing process. Thus, the data in FIG. 11 indicates that the barrier layer stacks having the manganese nitride layer, when formed with ten ALD soak cycles, are consistently resistant to copper diffusion at 500° C.

Thus, the use of the manganese-containing layers in the barrier layer stacks reduces the likelihood that the copper (seed) layers will dewet from the tantalum nitride layers, while also reducing the diffusion of copper.

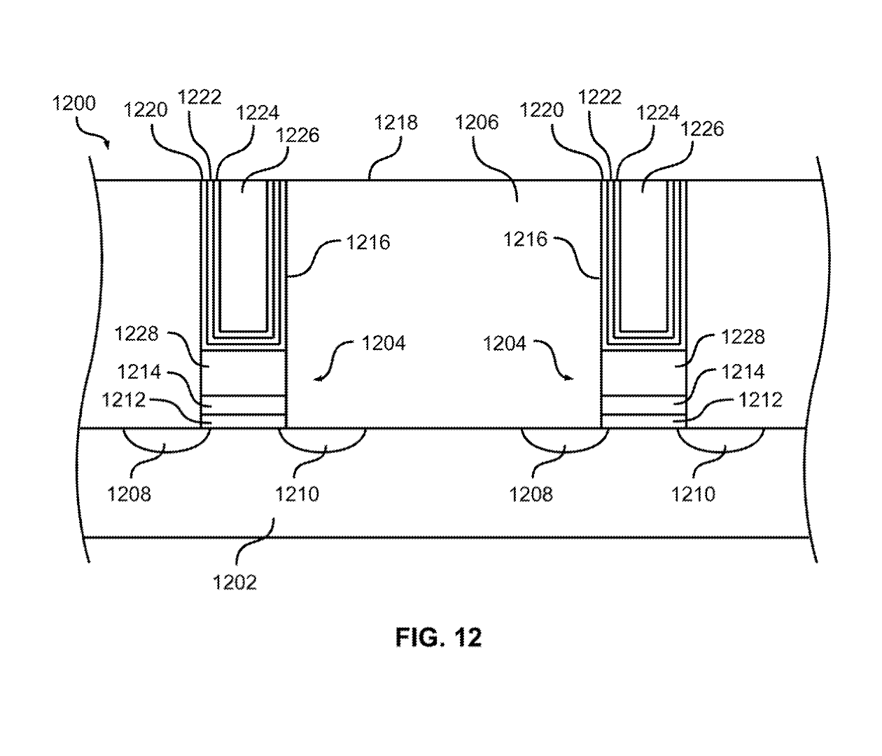

FIG. 12 is a simplified (or schematic) cross-sectional view of a microelectronic assembly 1200 according to some embodiments. The microelectronic assembly 1200 includes a substrate 1202 with microelectronic devices 1204 formed thereon and a dielectric layer (e.g., ILD) 1206 formed above the microelectronic devices 1204.

In some embodiments, the substrate 1202 includes (or is made of) a semiconductor material (e.g., silicon, germanium, etc.). In the example shown in FIG. 12, the microelectronic devices 1204 are transistors (e.g., metal-oxide-semiconductor field-effect transistors (MOSFETs), each of which includes a source region (or electrode) 1208, a drain region 1210, a gate dielectric layer 1212, and a gate electrode 1214.

The dielectric layer 1206 has trenches (or via trenches) 1216 formed in an upper surface 1218 thereof. In the example shown, the trenches 1216 are each vertically aligned with the gate electrode 1214 of one of the microelectronic devices 1204. Within each of the trenches 1216 a first barrier layer 1220, a second barrier layer 1222, a seed layer 1224, and a via (or interconnect) 1226 are formed. The first barrier layer 1220, the second barrier layer 1222, and the seed layer 1224 may be formed in the same manner to the similarly named components described above. The via 1226 may be made of copper and be formed in a manner similar to the copper body 110 described above.

The via 1226, as well as the layers 1220, 1222, and 1224, formed in each trench 1216 may be electrically connected (or coupled) to, for example, the gate electrode 1214 of the respective microelectronic device 1204 through a plug 1228 (e.g., tungsten, aluminum, etc.). Although the vias 1226 (and layers 1220, 1222, and 1224) are shown as being directly connected to the microelectronic devices 1204, it should be understood that in some embodiments, additional dielectric layers (and corresponding trenches, vias, etc.) are included in the microelectronic assembly.

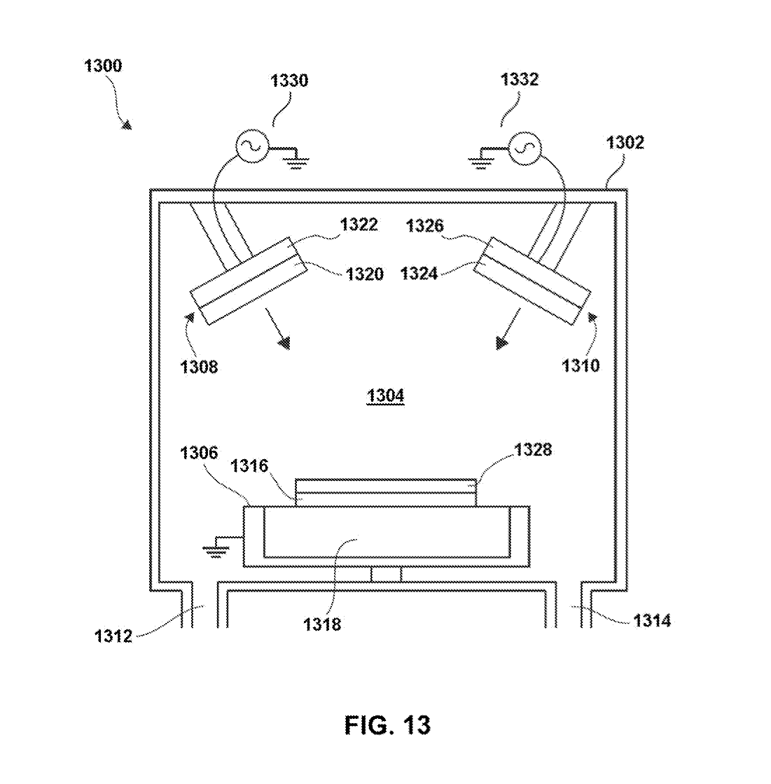

FIG. 13 provides a simplified illustration of a physical vapor deposition (PVD) tool (and/or system) 1300 which may be used, in some embodiments, to form at least some components of the copper barriers (or barrier layer stacks) described above and/or of the microelectronic assembly 1200 (FIG. 12). The PVD tool 1300 shown in FIG. 13 includes a housing 1302 that defines, or encloses, a processing chamber 1304, a substrate support 1306, a first target assembly 1308, and a second target assembly 1310.

The housing 1302 includes a gas inlet 1312 and a gas outlet 1314 near a lower region thereof on opposing sides of the substrate support 1306. The substrate support 1306 is positioned near the lower region of the housing 1302 and is configured to support a substrate 1316. The substrate 1316 may be a round substrate having a diameter of, for example, about 200 mm or about 300 mm. In other embodiments (such as in a manufacturing environment), the substrate 1316 may have other shapes, such as square or rectangular, and may be significantly larger (e.g., about 0.5 to about 4 m across). The substrate support 1306 includes a support electrode 1318 and is held at ground potential during processing, as indicated.

The first and second target assemblies (or process heads) 1308 and 1310 are suspended from an upper region of the housing 1302 within the processing chamber 1304. The first target assembly 1308 includes a first target 1320 and a first target electrode 1322, and the second target assembly 1310 includes a second target 1324 and a second target electrode 1326. As shown, the first target 1320 and the second target 1324 are oriented or directed towards the substrate 1316. As is commonly understood, the first target 1320 and the second target 1324 include one or more materials that are to be used to deposit a layer of material 1328 on the upper surface of the substrate 1316.

The materials used in the targets 1320 and 1324 may, for example, include manganese, tantalum, tin, zinc, silicon, silver, aluminum, molybdenum, zirconium, hafnium, titanium, copper, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although two targets 1320 and 1324 are shown, a different number of targets may be used (e.g., one or more than two).

The PVD tool 1300 also includes a first power supply 1330 coupled to the first target electrode 1322 and a second power supply 1332 coupled to the second target electrode 1324. As is commonly understood, in some embodiments, the power supplies 1330 and 1332 pulse direct current (DC) power to the respective electrodes, causing material to be, at least in some embodiments, simultaneously sputtered (i.e., co-sputtered) from the first and second targets 1320 and 1324. In some embodiments, the power is alternating current (AC) to assist in directing the ejected material towards the substrate 1316.

During sputtering, inert gases (or a plasma species), such as argon or krypton, may be introduced into the processing chamber 1304 through the gas inlet 1312, while a vacuum is applied to the gas outlet 1314. The inert gas(es) may be used to impact the targets 1320 and 1324 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 13, the PVD tool 1300 may also include a control system having, for example, a processor and a memory, which is in operable communication with the other components shown in FIG. 13 and configured to control the operation thereof in order to perform the methods described herein.

Although the PVD tool 1300 shown in FIG. 13 includes a stationary substrate support 1306, it should be understood that in a manufacturing environment, the substrate 1316 may be in motion (e.g., an in-line configuration) during the formation of various layers/components described herein.

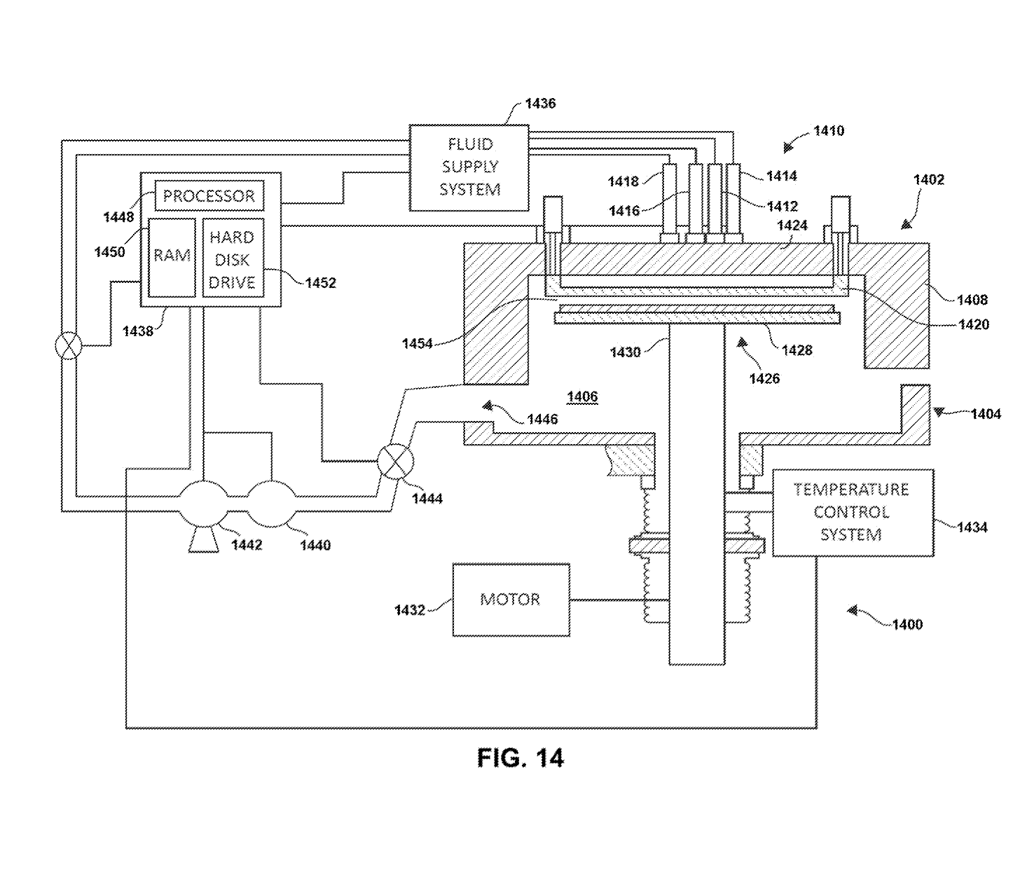

FIG. 14 provides a simplified illustration of an atomic layer deposition (ALD) tool (and/or system) 1400 which may be used, in some embodiments, to form at least some components of the copper barriers (or barrier layer stacks) described above and/or of the microelectronic assembly 1200 (FIG. 12).

The tool (or chamber) 1400 includes an enclosure assembly 1402 formed from a process-compatible material, such as aluminum or anodized aluminum. The enclosure assembly 1402 includes a housing 1404, which defines a processing chamber 1406, and a vacuum lid assembly 1408 covering an opening to the processing chamber 1406 at an upper end thereof. Although only shown in cross-section, it should be understood that the processing chamber 1406 is enclosed on all sides by the housing 1404 and/or the vacuum lid assembly 1408.

A process fluid injection assembly 1410 is mounted to the vacuum lid assembly 1408 and includes a plurality of passageways (or injection ports) 1412, 1414, 1416, and 1418 and a showerhead 1420 to deliver reactive and carrier fluids into the processing chamber 1406. In the embodiment depicted in FIG. 14, the showerhead 1420 is moveably coupled to an upper portion of the vacuum lid assembly 1408 (i.e., a backing plate 1424). The showerhead 1420 may be formed from any known material suitable for the application, including stainless steel, aluminum, anodized aluminum, nickel, ceramics and the like.

Referring again to FIG. 14, the tool 1400 also includes a heater/lift assembly 1426 disposed within processing chamber 1406. The heater/lift assembly 1426 includes a support pedestal (or substrate support) 1428 connected to an upper portion of a support shaft 1430. The support pedestal 1428 is positioned between shaft 1430 and the backing plate 1424 and may be formed from any process-compatible material, including aluminum nitride and aluminum oxide. The support pedestal 1428 is configured to hold or support a substrate and may be a vacuum chuck, as is commonly understood, or utilize other conventional techniques, such as an electrostatic chuck (ESC) or physical clamping mechanisms, to prevent the substrate from moving on the support pedestal 1428. The support shaft 1430 is moveably coupled to the housing 1404 so as to vary the distance between support pedestal 1428 and the backing plate 1424. That is, the support shaft 1430 may be vertically moved to vary the distance between the support pedestal 1428 and the backing plate 1424. In the depicted embodiment, a lower portion of the support shaft 1430 is coupled to a motor 1432 which is configured to perform this movement. Although not shown, a sensor may provide information concerning the position of the support pedestal 1428 within processing chamber 1406.

The support pedestal 1428 may be used to heat the substrate through the use of heating elements (not shown) such as resistive heating elements embedded in the pedestal assembly. In the embodiment shown in FIG. 14, a temperature control system 1434 is provided to control the heating elements, as well as maintain the chamber housing 1404, vacuum lid assembly 1408, and showerhead 1420 within desired temperature ranges in a conventional manner.

Still referring to FIG. 14, the tool 1400 also includes a fluid supply system 1436 and a controller (or system control system) 1438. The fluid supply system 1436 is in fluid communication with the passageways 1412, 1414, 1416, and 1418 through a sequence of conduits (or fluid lines).

The fluid supply system 1436 (and/or the controller 1438) controls the flow of processing fluids to, from, and within the processing chamber 1406 are with a pressure control system that includes, in the embodiment shown, a turbo pump 1440 and a roughing pump 1442. The turbo pump 1440 and the roughing pump 1442 are in fluid communication with processing chamber 1406 via a butterfly valve 1444 and a pump channel 1446.

The controller 1438 includes a processor 1448 and memory, such as random access memory (RAM) 1450 and a hard disk drive 1452. The controller 1438 is in operable communication with the various other components of the tool 1400, including the turbo pump 1440, the temperature control system 1434, the fluid supply system 1436, and the motor 1432 and controls the operation of the entire tool to perform the methods and processes described herein.

During operation, the tool 1400 establishes conditions in a processing region 1454 between an upper surface of the substrate and the showerhead 1420, such as injecting precursors (or reagents), as well as purge gases, to form the desired material on the surface of the substrate.

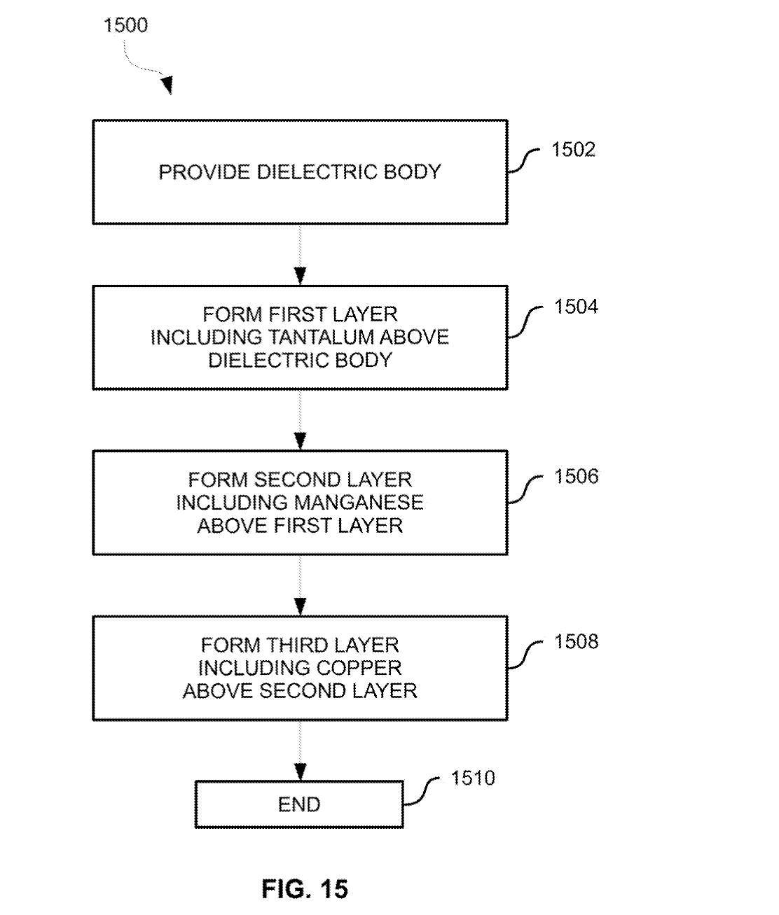

FIG. 15 is a flow chart illustrating a method 1500 for forming a copper barrier according to some embodiments. At block 1502, a dielectric body 100 is provided. In some embodiments, the dielectric body is made of a dielectric material, such as silicon oxide, silicon nitride, a high-k dielectric (e.g., having a dielectric constant greater than 3.9), such as zirconium oxide, hafnium oxide, or aluminum oxide, or a combination thereof. In some embodiments, the dielectric body is a dielectric layer formed above a substrate (e.g., semiconductor), such an interlayer dielectric (ILD) with one or more trenches formed in a surface thereof.

At block 1504, a first layer (or first barrier layer) is formed above the dielectric body. In some embodiments, the first layer includes tantalum. The first layer may be made of tantalum nitride. In some embodiments, the first layer is formed using ALD and has a thickness of, for example, between about 0.3 nm and about 5 nm.

At block 1506, a second layer (or second barrier layer) is formed above the first layer. In some embodiments, the second layer includes manganese. The second layer may be made of manganese, manganese nitride, or a combination thereof. The second layer may have a thickness of, for example, between about 0.1 nm and about 5 nm.

In embodiments in which the second layer is made of manganese, the second layer may have a thickness of, for example, between about 0.5 nm and about 2.5 nm and be formed using PVD. In embodiments in which the second layer is made of manganese nitride, the second layer may have a thickness of, for example, between about 0.1 nm and about 0.5 nm and be formed using PVD or ALD.

At block 1508, a third layer (or seed layer) is then formed above the second layer. In some embodiments, the third layer is made of copper and has a thickness of, for example, between about 5 nm and about 100 nm. The third layer may be formed using, for example, PVD.

In some embodiments, the first, second, and third layer are formed within a trench formed in the surface of the ILD. Although not shown, the method 1500 may also include forming a copper body (e.g., a copper via) above the third layer, within the trench. Further, in some embodiments, the method further includes forming other components of a microelectronic assembly above a substrate, such as those shown in FIG. 12. At block 1510, the method ends.

Thus, in some embodiments, methods for forming a copper barrier are provided. A dielectric body is provided. A first layer is formed above the dielectric body. The first layer includes tantalum. A second layer is formed above the first layer. The second layer includes manganese. A third layer is formed above the second layer. The third layer includes copper.

In some embodiments, methods are provided. A substrate including a dielectric layer is provided. The dielectric layer has a trench formed in a surface thereof. A first barrier layer is formed above the dielectric layer within the trench. The first barrier layer includes tantalum. A second barrier layer is formed above the first barrier layer. The second barrier layer includes manganese. A seed layer is formed above the second barrier layer. The seed layer includes copper. A copper body is formed within the trench above the seed layer.

In some embodiments, microelectronic assemblies are provided. Each microelectronic assembly includes a substrate having a dielectric layer formed above. A first barrier layer is formed above the dielectric layer. The first barrier layer includes tantalum. A second barrier layer is formed above the first barrier layer. The second barrier layer includes manganese. A seed layer is formed above the second barrier layer. The seed layer includes copper. A copper body is formed above the seed layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a copper interconnect, the method comprising:
providing a dielectric;
forming a first layer above the dielectric, wherein the first layer comprises tantalum;
forming a second layer above the first layer, wherein the second layer comprises manganese; and
forming a third layer above the second layer, wherein the third layer comprises copper.

2. The method of claim 1, wherein the second layer has a thickness of between about 0.1 nanometer (nm) and about 5 nm.

3. The method of claim 2, wherein the second layer is formed using physical vapor deposition (PVD) or atomic layer deposition (ALD).

4. The method of claim 3, wherein the first layer comprises tantalum nitride.

5. The method of claim 4, wherein the first layer has a thickness of between about 0.3 nm and about 5 nm.

6. The method of claim 5, wherein the first layer is formed using ALD.

7. The method of claim 3, wherein the second layer has a thickness of between about 0.5 nm and about 2.5 nm and is formed using PVD.

8. The method of claim 3, wherein the second layer comprises manganese nitride and has a thickness of between about 0.1 nm and about 0.5 nm.

9. The method of claim 3, wherein the third layer has a thickness of between about 5 nm and about 100 nm.

10. The method of claim 3, wherein the dielectric comprises silicon oxide, silicon nitride, or a combination thereof.

11. A method comprising:
providing a substrate comprising a dielectric layer, wherein the dielectric layer has a trench formed in a surface thereof;
forming a first barrier layer above the dielectric layer within the trench, wherein the first barrier layer comprises tantalum;
forming a second barrier layer above the first barrier layer, wherein the second barrier layer comprises manganese;
forming a seed layer above the second barrier layer, wherein the seed layer comprises copper; and
forming a copper conductor within the trench above the seed layer.

12. The method of claim 11, wherein the second barrier layer has a thickness of between about 0.5 nanometers (nm) and about 2.5 nm and is formed using physical vapor deposition (PVD).

13. The method of claim 11, wherein the second barrier layer comprises manganese nitride, has a thickness of between about 0.1 nm and about 0.5 nm, and is formed using physical vapor deposition (PVD) or atomic layer deposition (ALD).

14. The method of claim 11, wherein the first barrier layer comprises tantalum nitride, has a thickness of between about 0.5 nm and about 5 nm, and is formed using atomic layer deposition (ALD).

15. The method of claim 11, wherein the substrate further comprises a microelectronic device formed thereon, the dielectric layer being formed above the microelectronic device, and wherein the copper conductor is electrically connected to the microelectronic device.

16. A microelectronic assembly comprising:
a substrate having a dielectric layer;
a first barrier layer formed above the dielectric layer, wherein the first barrier layer comprises tantalum;
a second barrier layer formed above the first barrier layer, wherein the second barrier layer comprises manganese;
a seed layer formed above the second barrier layer, wherein the seed layer comprises copper; and
a copper conductor formed above the seed layer.

17. The method of claim 16, wherein the first barrier layer comprises tantalum nitride and has a thickness of between about of between about 0.3 nm and about 5 nm.

18. The method of claim 17, wherein the second barrier layer has a thickness of between about 0.5 nm and about 2.5 nm.

19. The method of claim 17, wherein the second barrier layer comprises manganese nitride and has a thickness of between about 0.1 nm and about 0.5 nm.

20. The method of claim 17, wherein the substrate further comprises a microelectronic device formed thereon, the dielectric layer being formed above the microelectronic device, and wherein the dielectric layer formed in an upper surface thereof, the first barrier layer, the second barrier layer, the seed layer, and the copper conductor being formed within the trench, the copper conductor being electrically connected to the microelectronic device.
